(19) United States
(12) Patent Application Publication
(10) Pub. No.: US 2026/0219036 A1
(43) Pub. Date: Jul. 30, 2026

(54) MEASURING SYSTEM FOR OPTICALLY CHECKING AN ALIGNMENT STATE, METHOD FOR OPTICALLY CHECKING AN ALIGNMENT STATE, ALIGNMENT METHOD

(71) Applicant: Carl Zeiss SMT GmbH, Oberkochen (DE)

(72) Inventors: Bastian Kern-Mareis, Aalen (DE); Andreas Koeniger, Aalen (DE)

(21) Appl. No.: 19/461,846

(22) Filed: Jan. 28, 2026

(30) Foreign Application Priority Data
Jan. 28, 2025 (DE) 102025103005.7

(51) Int. Cl. G01B 11/27; G01N 21/956; G03F 1/84; G03F 7/00

(52) U.S. Cl. CPC G01B 11/27; G01N 21/956; G03F 1/84; G03F 7/70141; G03F 7/70258; G03F 7/706; G03F 7/70833; G03F 7/7085; G01N 2021/95676

(57) ABSTRACT

A measuring system for optically checking an alignment state of an illumination optics unit relative to a projection optics unit. The illumination optics unit is designed to illuminate an object situated in an object plane of the projection optics unit, and the projection optics unit is designed to image a reflection generated at the object into an image plane of the projection optics unit. The measuring system comprises: a mount for positioning the illumination optics unit and the projection optics unit; a partially transparent test object arranged in the object plane; a measurement illumination unit for generating a measurement beam path, which illuminates a test field of the test object at the rear and is oriented such that the test field is imaged onto a first sensor plane by the illumination optics unit and imaged onto a second sensor plane by the projection optics unit; a first sensor for capturing an image representation generated in the first sensor plane; a second sensor for capturing an image representation generated in the second sensor plane; a stop device arranged in the measurement beam path between an illumination source and the object plane and comprising a plurality of pixels which are each switchable between a first transmission state and a second transmission state; and a control unit for switching the plurality of pixels between the first transmission state and the second transmission state. As a result of the switchable pixels of the stop device, the measurement beam path can be flexibly adapted to the measurement task without manipulating mechanical elements.

### CROSS-REFERENCE TO RELATED APPLICATION

This application claims benefit under 35 U.S.C. §119 to German Patent Application 10 2025 103 005.7, filed on Jan. 28, 2025, the entire content of which is incorporated herein by reference.

### TECHNICAL FIELD

The subject matter of the invention relates to a measuring system for optically checking an alignment state of an illumination optics unit relative to a projection optics unit, to a method for optically checking an alignment state and to a corresponding alignment method. The illumination optics unit and the projection optics unit may in particular be part of a mask inspection apparatus for validating photomasks for semiconductor lithography.

### BACKGROUND

Semiconductor lithography is used for producing microstructured components, such as integrated circuits. The microlithography process is carried out in what is known as a projection exposure apparatus, which has an illumination system and a projection system. The image of a photomask (also called “reticle”) illuminated by use of the illumination system is projected in this case with the aid of the projection system onto a substrate—for example a silicon wafer—that is coated with a light-sensitive layer (so-called “photoresist”) and is arranged in the image plane of the projection system, in order to transfer the mask structure to the coated substrate. In subsequent production steps, the transferred structure is implemented in the substrate, e.g., by etching or material deposition.

To ensure a high quality of the imaging generated on the coated substrate, it is necessary for the mask to be true to size and not adversely affected by contaminations. It is known practice to subject photomasks to an inspection, either prior to the operation in a microlithographic projection exposure apparatus or during a break in operation. To this end, a so-called aerial image of the mask or of a portion of the mask is generated with the aid of a mask inspection apparatus, the photomask in the process being imaged onto a photosensor, rather than onto the coated substrate. Using the imaging onto the photosensor as a basis, it is possible to assess whether the photomask is without defects and contaminations. In order to inspect the photomask with the greatest possible accuracy, the illumination optics unit and the projection optics unit in the mask inspection apparatus need to be aligned very accurately with respect to each other.

### SUMMARY

The problem addressed by the present invention is that of providing a measuring system for optically checking an alignment state of an illumination optics unit relative to a projection optics unit, a corresponding method for optically checking the alignment state and an alignment method, which can all achieve increased accuracy. This problem is solved by the features of the independent claims. Advantageous embodiments are described in the dependent claims.

Accordingly, the invention relates to a measuring system for optically checking an alignment state of an illumination optics unit relative to a projection optics unit. The illumination optics unit is designed to illuminate an object situated in an object plane of the projection optics unit. Moreover, the projection optics unit is designed to image a reflection generated at the object into an image plane of the projection optics unit. The measuring system comprises:
a mount for positioning the illumination optics unit and the projection optics unit;
a partially transparent test object arranged in the object plane;
a measurement illumination unit for generating a measurement beam path, which illuminates a test field of the test object at the rear and is oriented such that the test field is imaged onto a first sensor plane by the illumination optics unit and imaged onto a second sensor plane by the projection optics unit;
a first sensor for capturing an image representation of the test field generated in the first sensor plane;
a second sensor for capturing an image representation of the test field generated in the second sensor plane;
a stop device arranged in the measurement beam path between an illumination source and the object plane and comprising a plurality of pixels which are each switchable between a first transmission state and a second transmission state which differs from the first; and
a control unit for switching the plurality of pixels between the first transmission state and the second transmission state.

The measurement beam path is incident on the test object at the rear, i.e., the side of the test object opposite the illumination optics unit and the projection optics unit, and can in particular illuminate the test field of the test object there, and this test field can be imaged onto the first sensor by way of a first partial beam of the measurement beam path through the illumination optics unit and moreover imaged onto the second sensor by way of a second partial beam of the measurement beam path through the projection optics unit. The test object is suitable for enabling an alignment of the illumination optics unit relative to the projection optics unit and, to this end, may comprise suitable markings, for example, which can be detected by the sensors. For example, the sensors could be charge coupled device (CCD) sensors or complementary metal oxide semiconductor (CMOS) sensors. Each sensor can have, e.g., an array of individually addressable sensing elements or pixels.

The illumination optics unit and the projection optics unit may be introduced into the measuring system in order to be measured therein. To this end, provision may be made for the projection optics unit and the illumination optics unit to be affixed to a carrier device which can be introduced into the measuring system. For example, the mount may comprise a bearing surface on which the carrier device is positioned. Positioning the illumination optics unit and the projection optics unit results in these adopting a defined state relative to the measurement beam path generated by the measurement illumination unit. In that case, the illumination optics unit and the projection optics unit can be aligned both relative to the measurement beam path and relative to each other. For example, provision may be made for the image representation of the test field captured on the sensors to be modified by suitable alignment measures until a desired result is achieved on both sensors. As a result of the alignment measures it is possible to align an exit pupil of the illumination optics unit relative to an entrance pupil of the projection optics unit, wherein in particular the opening cross sections of the pupils and/or the orientations of the pupils

can be aligned relative to each other. To this end, the projection optics unit and the illumination optics unit may comprise suitable calibration equipment that is used to implement the alignment. After carrying out the alignment, the illumination optics unit and the projection optics unit can be removed from the measuring system again in an aligned state and can be installed, and used, in an optical system, in particular in a mask inspection apparatus.

By virtue of the illuminated test field being imaged onto a respective sensor both by the illumination optics unit and by the projection optics unit, the measurement beam path divides into a first partial beam and a second partial beam following the passage through the test object. A problem that may arise when a joint measurement beam path is divided into two partial beams which image the illuminated test field of the test object onto the two sensors is that the measurement of one of the partial beams may be affected by unwanted reflections off the test object due to the respective other partial beam, and these reflections may also be incident on the sensor and thus falsify the measurement. The generation of a spatially delimited measurement beam used to image the illuminated test field on only one of the sensors by way of only one of the optical units in each case was therefore known in principle in the prior art, with the measurement illumination unit being configured to be pivotable about a central fixed point located in the object plane for measuring the respective other optical unit in this case. Unwanted reflections can be reduced because the measurement beam is in this case more narrowly delimited and directly oriented on the respective sensor used. However, an insight gained within the scope of the invention is that the displacement of the measurement illumination unit introduces mechanical vibrations into the measuring system, and these may lead to a misalignment of the components of the measuring system, whereby the measurement accuracy is reduced.

By contrast, with the aid of the stop device according to the invention, a portion of the measurement beam path may simply be masked without this requiring a mechanical displacement of components of the measuring system. As a result, it is possible to successively perform a respective measurement using one of the partial beams, while the respective other partial beam can be masked by the stop device such that unwanted reflections are avoided. Moreover, the control unit can optionally allow either the passage or at least partial masking of a beam of the measurement beam path corresponding to the respective pixel. This may generate a desired measurement beam profile serving to flexibly adapt the measurement beam path to the measurement task at hand.

In an embodiment, the control unit is designed to optionally switch a first pixel into one of the two transmission states independently of a switching state of a second pixel different from the first. In particular, provision can also be made for each of the plurality of pixels to be capable of being optionally switched into one of the various transmission states independently of a switching state of the other pixels. Furthermore, the plurality of pixels can also be switchable into multiple transmission states that differ from one another. In the present case, different transmission states differ in terms of a transmission rate of the respective pixel. It is also possible to set quite complex measurement beam profiles as a result of the independent switchability of the pixels into the different transmission states. For example, this may allow compensation for aberrations present in the optical unit to be adjusted, whereby the accuracy of the adjustment can be further improved.

In an embodiment, the stop device comprises a pixel unit in the form of a liquid crystal display. In this case, the pixels in a manner known in principle may be formed from liquid crystal segments which are capable of changing their transparency independently of one another, for example, by virtue of the orientation of the liquid crystals being changed by the application of a voltage.

The stop device may furthermore comprise a pixel unit comprising an absorption modulation material. Absorption modulation materials have an absorptance or transmittance that is modifiable by irradiation with light with a predetermined wavelength for the material. US 2014/0300877 A1 proposes the use of such an absorption modulation material to create a photolithographic mask, in order to be able to adapt the mask structures as desired. In the present case, individual pixels in the pixel unit may consist of segments which may be provided with a desired transmittance by way of being irradiated with a suitable wavelength. In this embodiment, too, the pixels may thus be switched between different transmission states by being irradiated with a suitable wavelength. In this case, the measuring system may comprise an irradiation source which is controllable by the control unit and which is designed to irradiate individual pixels in each case with a wavelength suitable for modifying the transmission state.

The stop device may also comprise a pixel unit formed by a microelectromechanical system (MEMS). In a manner known in principle, the MEMS also allows individual pixels to be switched between different transmission states without (macroscopic) mechanical vibrations being introduced into the system.

In an embodiment, the stop device comprises two pixel units, the pixels of which are oriented in such a way relative to one another that an achievable contrast ratio between the first transmission state and the second transmission state is increased. Provision may be made for the pixel units to be positioned parallel to each other and in particular perpendicular to the measurement beam path. A pixel in one of the pixel units is assigned to a corresponding pixel in the other pixel unit and can be switched simultaneously. Should the intention be to mask a partial beam of the measurement beam, the two mutually corresponding pixels are switched into a transmission state with a low transmittance such that the light beam loses intensity when passing through each of the two corresponding pixels. The contrast can be increased significantly in this way. It is also possible to combine more than two pixel units aligned with one another, for example three to five pixel units, to form a stop device.

In an embodiment, the stop device comprises at least one of the following features:
a pixel dimension is between 100 μm and 400 μm;
a number of pixels is between 100 and 1000; and
a contrast ratio of the stop device between the first transmission state and the second transmission state is between 1:10⁶ and 1:3×10⁷.
   It was found that these features allow an accuracy to be obtained which is sufficient for the alignment and inspection of a mask inspection apparatus.

Provision may be made for the control unit to be capable of switching any pixel of the stop device into an intermediate state in which a transmittance of the pixel is greater than in the first transmission state and less than in the second transmission state. In particular, the control unit can switch any pixel into a plurality of intermediate states in each of which the pixel has a different transmittance, the transmittances being between the transmittance in the first transmission state and the transmittance in the second transmission state. The measurement beam profile can be set even more flexibly by virtue of the pixels being capable of being switched into an intermediate state or else into multiple mutually different intermediate states. In particular, this can allow the compensation of aberrations, which are expected within the illumination optics unit or the projection optics unit, by way of a suitable measurement beam profile.

The subject matter of the invention furthermore relates to a method for optically checking an alignment state of an illumination optics unit relative to a projection optics unit. The illumination optics unit is designed to illuminate an object situated in an object plane of the projection optics unit. Moreover, the projection optics unit is designed to image a reflection generated at the object into an image plane of the projection optics unit. The method comprises the following steps:
arranging a partially transparent test object in the object plane;
generating a measurement beam path, which illuminates a test field of the test object at the rear and is oriented such that the test field is imaged onto a first sensor plane by the illumination optics unit and imaged onto a second sensor plane by the projection optics unit;
positioning a stop device in the measurement beam path between the illumination source and the object plane, wherein the stop device comprises a plurality of pixels which are each switchable between a first transmission state and a second transmission state;
controlling the plurality of pixels in order to generate a predetermined measurement beam profile;
capturing an image representation of the test field generated by the illumination optics unit and/or an image representation of the test field generated by the projection optics unit.

The disclosure comprises further embodiments of the method which may be developed by features already described above in connection with the measuring system according to the invention. Moreover, the disclosure comprises further embodiments of the measuring system which may be developed by features described in connection with the method.

In an embodiment, the image representation of the test field generated by the illumination optics unit is captured while the second measurement beam is at least partially masked, wherein the image representation of the test field generated by the projection optics unit is captured while the first measurement beam is at least partially masked.

Provision may be made for an expected optical aberration of the illumination optics unit or an expected optical aberration of the projection optics unit to be estimated. Furthermore, the predetermined measurement beam profile may be generated in such a way that the expected optical aberration of the illumination optics unit or of the projection optics unit is at least partially compensated for.

For example, the expected aberration may be caused by manufacturing or positioning inaccuracies of the optical elements or else by systematic inaccuracies in the measuring technology. The optical aberration may also be an apodization of the illumination optics unit and/or of the projection optics unit. An image representation of the measurement field with an intensity that is as homogeneous as possible is generated in the sensor plane as a result of the compensation. This improves the alignment accuracy. The expected optical aberration may be estimated in a manner known in principle, for example, with the aid of empirical values or with the aid of mathematical calculations.

In an embodiment, the image representation of the test field generated by the illumination optics unit and/or by the projection optics unit is used to estimate an optical aberration of the illumination optics unit and/or of the projection optics unit, wherein the predetermined measurement beam profile is generated in such a way that the estimated optical aberration of the illumination optics unit and/or of the projection optics unit is at least partially compensated for. In this embodiment, a measurement is performed first in order to estimate possibly present optical aberrations of the illumination optics unit or of the projection optics unit on the basis of the measurement result, wherein the measurement beam profile is only adapted accordingly in a subsequent measurement in order to compensate for the measured optical aberration.

The subject matter of the invention furthermore relates to a method for aligning an illumination optics unit relative to a projection optics unit, wherein a method according to the invention for optically checking an alignment state of an illumination optics unit relative to a projection optics unit is performed, wherein the image representation of the test field generated by the illumination optics unit and the image representation of the test field generated by the projection optics unit are used to align the illumination optics unit relative to the projection optics unit.

### BRIEF DESCRIPTION OF DRAWINGS

Advantageous embodiments are explained by way of example below with reference to the accompanying drawings, in which:

FIG. 1: shows a schematic illustration of a mask inspection apparatus;

FIG. 2: shows a schematic illustration of a measuring system according to the invention;

FIG. 3: shows a schematic illustration of the stop device in the measuring system from FIG. 2 in a first state;

FIG. 4: shows a schematic illustration of the stop device in the measuring system from FIG. 2 in a second state;

FIG. 5: shows a schematic illustration of the stop device in the measuring system from FIG. 2 in a third state;

FIG. 6: shows a schematic illustration of the measuring system from FIG. 2 in a second state;

FIG. 7: shows a schematic illustration of the measuring system from FIG. 2 in a third state;

FIG. 8: shows a schematic illustration of the stop device in the measuring system from FIG. 2 in a fourth state;

FIG. 9: shows an illustration of a method for compensating for an apodization with the aid of the stop device in the measuring system from FIG. 2;

FIG. 10: shows an illustration of a method for compensating for an optical aberration with the aid of the stop device in the measuring system from FIG. 2.

### DETAILED DESCRIPTION

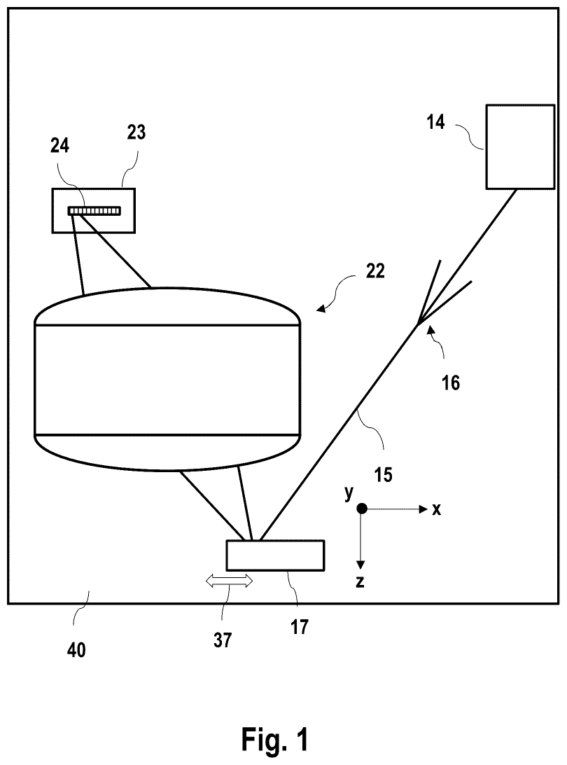

FIG. 1 shows a schematic illustration of a mask inspection apparatus for examining microlithographic photomasks 17. In general, microlithographic photomasks 17 are intended to be used in a microlithographic projection exposure apparatus (not illustrated). In the microlithographic projection exposure apparatus, the photomask 17 is illuminated with extreme ultraviolet radiation (EUV radiation) at a wavelength of, for example, 13.5 nm in order to image a structure formed on the photomask 17 onto the surface of a lithographic object in the form of a wafer. The wafer is coated with a photoresist that reacts to the EUV radiation. The measuring device is used to examine whether the measuring device meets the specifications and is free from contaminations.

According to FIG. 1, the photomask 17 is arranged in the measuring device in such a way that an EUV beam path 15 emanating from an EUV radiation source 14 is guided to the photomask 17 by way of an illumination system 16. The illumination system 16 is used to shape the EUV radiation to form a beam used to illuminate, with uniform brightness, an examination field on the surface of the photomask 17. The illuminated region may have dimensions of 0.5 mm×0.8 mm, for example. The edge lengths of the photomask 17 may be between 100 mm and 200 mm, for example. A field stop used to delimit the illuminated region to the examination field on the surface of the photomask 17 is arranged in the illumination system 16. With an XY-positioner 37, the photomask can be moved in the XY-plane in order to bring different examination fields into the region of the EUV beam path.

The EUV beam path 15 reflected off the photomask 17 continues through a projection lens 22 to an EUV camera 23, which is equipped with an image sensor 24. The projection lens is used to image the examination field 20 of the photomask 17 onto the image sensor 24 of the EUV camera 23. The EUV radiation source 14, the illumination system 16, the photomask 17, the projection lens 22 and the EUV camera 23 are arranged in a vacuum housing 40, in which a negative pressure prevails during the operation of the measuring device.

The EUV radiation source 14 is, e.g., a plasma radiation source, in which the EUV radiation is emitted from a plasma at a wavelength of, e.g., 13.5 nm. For example, tin is a medium that can be used to generate a plasma suitable for emitting such EUV radiation. A laser beam can be made to impinge on a droplet of the medium for the purpose of creating the plasma.

The mirrors in the illumination system 16 and the mirrors in the projection lens 22 are designed as EUV mirrors which have a particularly high reflectivity for EUV radiation. The optical surface of the EUV mirrors may be formed by a highly reflective coating. This may be a multilayer coating, in particular a multilayer coating having alternating layers of molybdenum and silicon. Using such a coating, it is possible to reflect approximately 70% of the incident EUV radiation.

The projection lens 22 has a magnification factor of more than 100. In order to be able to record the entirety of the image generated by the examination field 20 of the photomask 17, the area of the image sensor 24 is greater than the area of the examination field 20 in accordance with the magnification factor. For example, the image sensor 24 may have dimensions of the order of 100 mm to 200 mm.

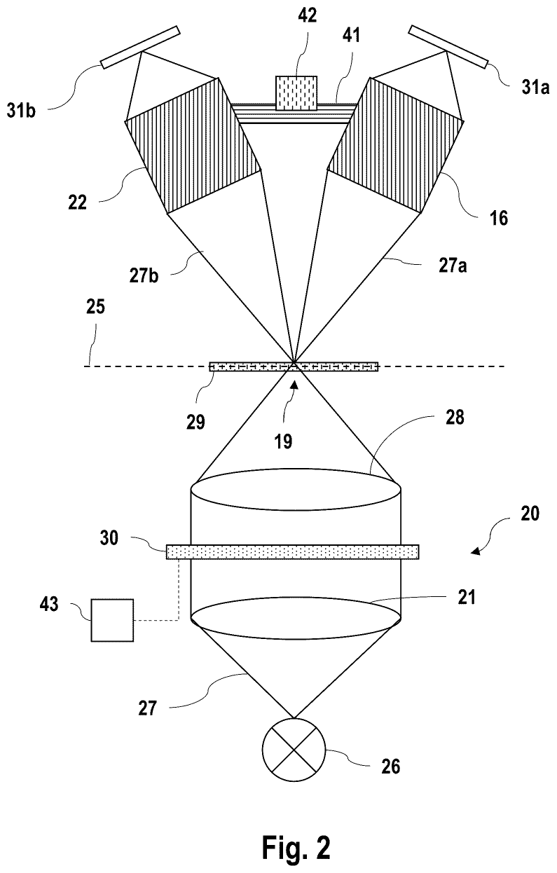

In order to enable a highly accurate measurement of the photomask 17, the illumination system 16 must be aligned very accurately relative to the projection system 22. In particular, it is necessary to ensure that the beam path generated by the illumination system 16 is incident on the photomask 17 at a correct angle and enters the projection optics unit at a correct angle and that an exit pupil of the illumination system 16 is exactly matched to an entrance pupil of the projection system. The alignment is performed with the aid of a measuring system according to the invention. Such a measuring system is described below in connection with FIG. 2. In particular, the alignment may be performed before the mask inspection apparatus is put into operation for the first time or else for maintenance purposes during an operating pause of the mask inspection apparatus. To this end, the illumination system 16 and the projection system 22 may be removed from the mask inspection apparatus and installed in the measuring system described below.

FIG. 2 shows a schematic illustration of a measuring system according to the invention for optically checking an alignment state of an illumination optics unit 16 relative to a projection optics unit 22. The illumination optics unit 16 and the projection optics unit 22 are secured to a carrier device 41 (not illustrated in FIG. 1) and may be introduced into the measuring system in this state so that a check of the alignment state and the actual alignment procedure can be performed within the measuring system. Once the alignment has been carried out, the carrier device 41 can be removed from the measuring system again together with the illumination optics unit 16 and the projection optics unit 22.

The measuring system comprises a measurement illumination unit 20 for generating a measurement beam path 27, a test object 29, a first sensor 31a and a second sensor 31b. Moreover, the measuring system comprises a mount 42, on which the carrier device 41 can be positioned in a predetermined orientation.

The measurement illumination unit 20 comprises an illumination source 26, the light of which is shaped into a parallel beam with the aid of a collimator 21. The beam path downstream of the collimator 21 contains a stop device 30 which, in a manner explained in detail below, is configured to provide the measurement beam path 27 with a desired measurement beam profile. Following the passage through the stop device 30, the measurement beam path reaches a condenser 28, which focuses the beam path onto a test field 19 of the test object 29. From the test field 19, the measurement beam path may reach into both the illumination optics unit 16 and the projection optics unit 22.

The test object 29 is positioned relative to the mount 42 in such a way that it is situated in an object plane 25 of the projection optics unit 22. Since the optical path along which light enters the illumination optics unit 16 in the measuring system of FIG. 2 is reversed to the optical path within the mask inspection apparatus of FIG. 1, the object plane 25 may in the present case (unlike in the mask inspection apparatus of FIG. 1) be considered to be the object plane 25 of the illumination optics unit 16 at the same time. The sensor 31a is situated in an image plane of the illumination optics unit 16, and the sensor 31b is situated in an image plane of the projection optics unit 22.

The test field 19 of the test object 29 is illuminated to the rear by the measurement beam path 27. The test object 29 is at least partially transparent so that the measurement beam path can at least partially pass through the test object 29. In the region of the test field 19, the test object 29 moreover comprises markings which facilitate the alignment procedure. Once the measurement beam path 27 has passed through the test object 29, a first portion 27a of the measurement beam path in the state shown in FIG. 2 passes into the illumination optics unit 16. In this way, the test field 19 is imaged onto a sensor surface of the sensor 31a by the illumination optics unit 16. Analogously, a second portion 27b of the measurement beam path in the state shown in FIG. 2 passes into the projection optics unit 22. In this way, the test field is imaged onto a sensor surface of the sensor 31b by the projection optics unit 22.

A problem that may arise in the state shown in FIG. 2 is that the image representation of the test field captured by the sensor 31a is disturbed by unwanted reflections that are attributable to the second portion 27b of the measurement beam 27. In order to avoid or at least reduce these unwanted reflections, the stop device 30 comprises a plurality of switchable pixels 32 which enable flexible setting of a desired measurement beam profile. To this end, the stop device 30 is connected to a control unit 43. In order to set a desired measurement beam profile, the control unit 43 transmits appropriate control signals to the stop device 30.

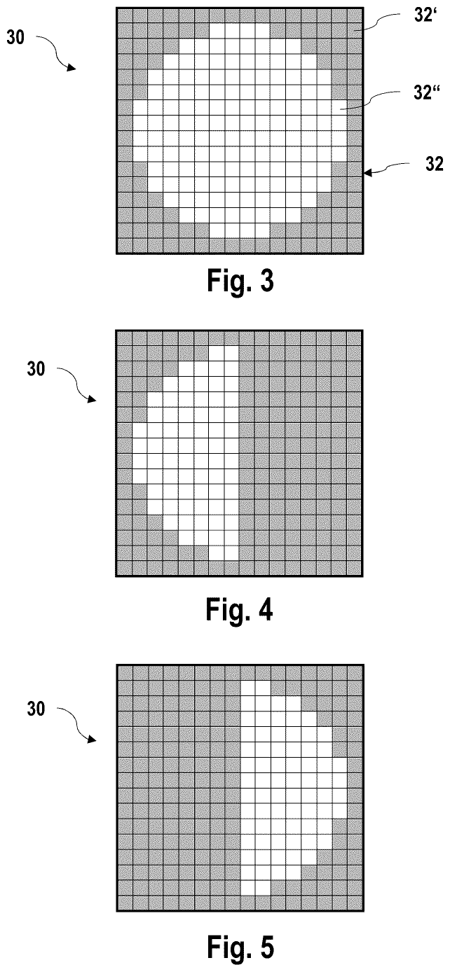

FIGS. 3 to 5 show the stop device 30 in various states which can be achieved by way of the control unit outputting appropriate control signals. The stop device 30 comprises a square pixel unit which in the present case consists of a total of 16 times 16 pixels 32 and in the present case is in the form of a liquid crystal display. A pixel 32 in the liquid crystal display is formed in a manner known in principle by a liquid crystal segment whose transmittance can be modified by applying a suitable voltage. In the present case, the emission of control signals by the control unit 43 may be accompanied by the application of a suitable voltage. The configuration of corresponding liquid crystal displays is known in principle and therefore need not be explained in detail in the present case.

In the state shown in FIG. 3, a first group of pixels 32″ is switched to a first transmission state with a high transmittance, in which said pixels are substantially transparent and allow the light to pass unimpeded. These pixels are illustrated by a white color in FIG. 3. A further group of pixels 32′ are switched into a state with a low transmittance, in which said pixels virtually completely mask the light. Pixels 32′ with a low transmittance are illustrated using a dark gray color in FIG. 3 and are also referred to as opaque pixels below. The transparent pixels 32″ form an approximately circular passage. A circular measurement beam profile can be generated by the switching state shown in FIG. 3.

In the state shown in FIG. 4, the transparent pixels 32″ form a semicircle which forms an opening situated on the left-hand side of the stop device 30. All other pixels 32′ have a low transmittance and mask the light.

In the state shown in FIG. 5, the transparent pixels 32″ form a semicircle which forms an opening situated on the right-hand side of the stop device 30. All other pixels 32′ have a low transmittance.

The states shown in FIGS. 3 and 4 allow the right-hand half and left-hand half, respectively, of the circular measurement beam to be masked, and hence a semicircular measurement beam profile can be generated.

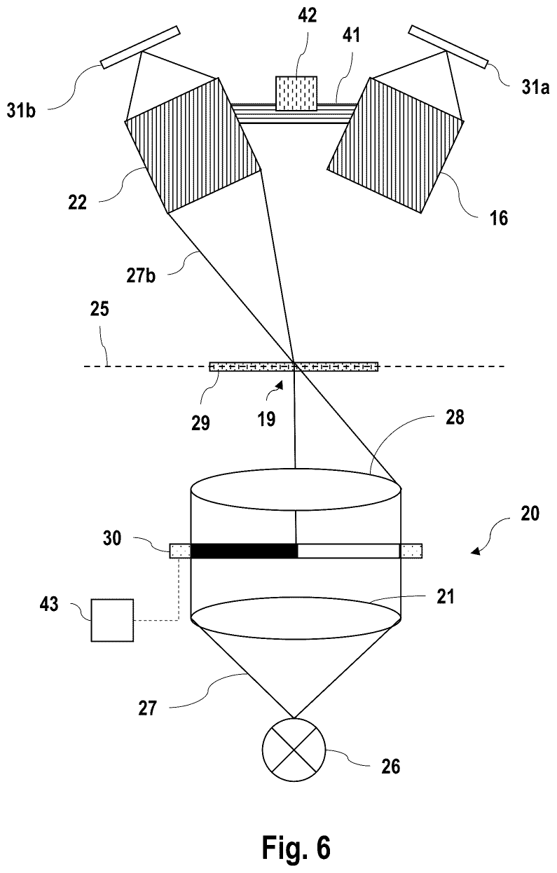

FIG. 6 shows the measuring system from FIG. 2 after the stop device 30 was switched into the state shown in FIG. 5, in which only a semicircular beam profile on the right-hand side of the stop device 30 is passed, while the entire left-hand half of the measurement beam 27 is masked. In this state, the test field 19 is illuminated only by the second portion 27b of the measurement beam 27, and only the second portion 27b of the measurement beam 27 reaches the sensor 31b by way of the projection optics unit 22. Masking the first portion 27a of the measurement beam avoids or at least reduces bothersome reflections, and so the test field 19 can be captured with high accuracy by the sensor 31b.

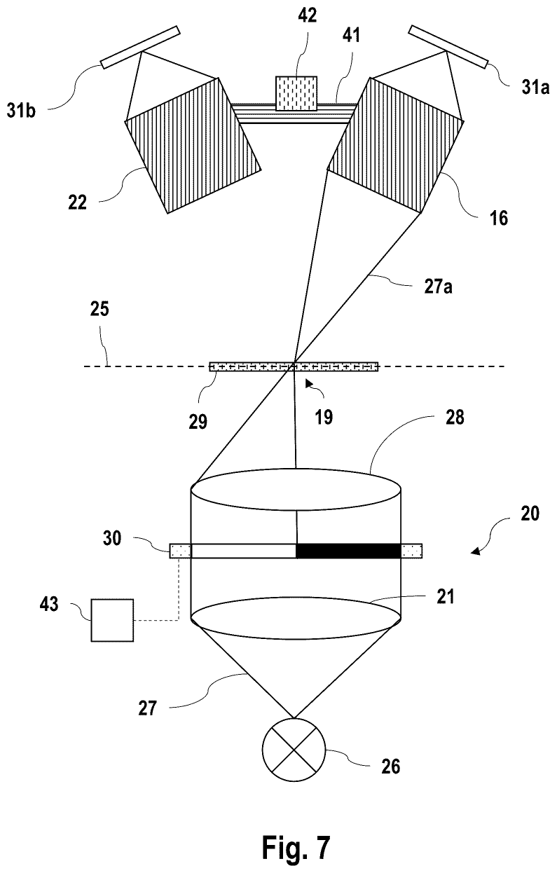

FIG. 7 shows the measuring system from FIG. 2 after the stop device 30 was switched into the state shown in FIG. 4, in which only a semicircular beam profile on the left-hand side of the stop device 30 is passed, while the entire right-hand half of the measurement beam 27 is masked. In this state, the test field 19 is illuminated only by the first portion 27a of the measurement beam 27, and only the first portion 27a of the measurement beam 27 reaches the sensor 31a by way of the illumination optics unit 22. Masking the second portion 27b of the measurement beam avoids or at least reduces bothersome reflections, and so the test field 19 can be captured with high accuracy by the sensor 31a.

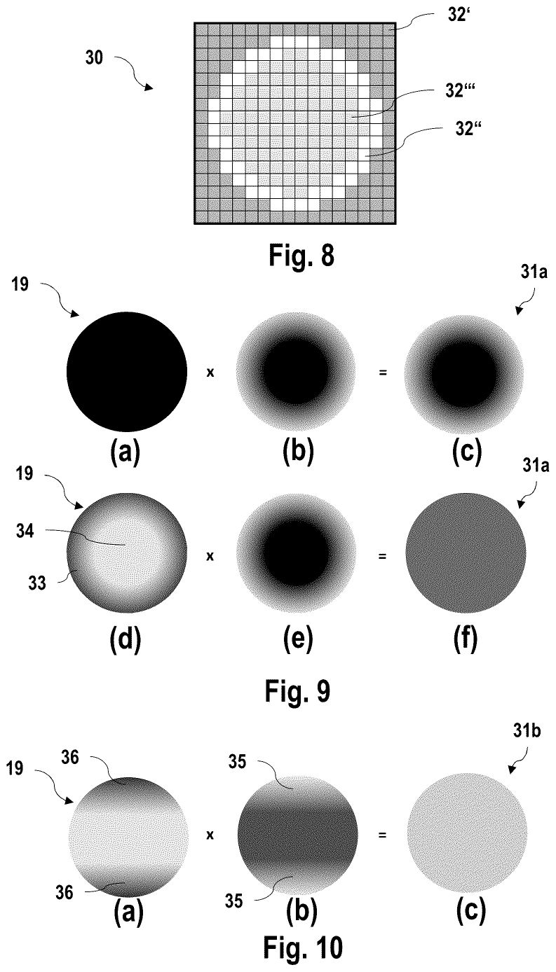

FIG. 8 shows the stop device 30 in a further switching state which is reached proceeding from the state shown in FIG. 3 by virtue of a third group of pixels 32′″ being switched into a state in which they have a middling transmittance between the transmittance of the transparent pixels 32″ and the transmittance of the opaque pixels 32′. These pixels 32′″ are also referred to as semi-transparent pixels below and are illustrated in FIG. 8 by a grayscale value between that of the transparent pixels 32″ and the opaque pixels 32′. The semi-transparent pixels 32′″ are situated within a circle in the center of the opening formed in FIG. 3 by the transparent pixels 32″ such that only an outer ring of transparent pixels 32″ still remains here. With the aid of the switching state of the stop device 30 shown in FIG. 8, it is for example possible to compensate for an optical aberration in the illumination optics unit 16 or in the projection optics unit 22. This will be explained in detail below on the basis of FIG. 9.

FIG. 9(a) shows a homogeneous pupil illumination which is generated by the measurement illumination unit 20 in the test field 19 and obtained by irradiating the test field 19 with a correspondingly homogeneous measurement beam profile. Such a measurement beam profile can be obtained by the switching state shown in FIG. 3, for example. A high level of illumination is illustrated by a darker color in FIG. 9, and a lower level of illumination is illustrated by a lighter color.

The homogeneously illuminated test field 19 is imaged onto the sensor 31a by way of the illumination system 16, and there it generates the inhomogeneous illumination which is shown in FIG. 9(c) and has a lower intensity in the edge region. From the measurement, it is possible to infer that what is known as apodization takes place within the illumination optics unit 16, as a result of which intensity losses occur in the edge region of the measurement beam path. The apodization of the illumination optics unit or the effect thereof on the measurement beam path is illustrated in FIG. 9(b). The intensity distribution from FIG. 9(c) is obtained by convolving the intensity distributions in FIG. 9(a) and 9(b), and this is indicated in the figures by the convolution operator “x”.

The extent of the apodization of the illumination optics unit 16 can be estimated from the measurement shown in FIG. 9(c), and from this it is possible to derive a measurement beam profile which should be generated by the measurement illumination unit 20 and which can be used to compensate for the apodization. In the present case, the measurement beam profile must be suitable for illuminating an edge region of the test field 19 more strongly in order to compensate for the intensity losses in the edge region caused by the apodization. A correspondingly illuminated test field 19 is illustrated in FIG. 9(d). The pupil illumination shown there can, for example, be obtained using a stop device 20 which is in the switching state shown in FIG. 8. The transparent pixels 32′″ situated in the edge region of the aperture lead to the outer region 33 of the test field 19 being illuminated more strongly than the central circular region of the aperture where the semi-transparent pixels 32′″ are situated. Owing to the apodization within the illumination optics unit 16, illustrated again in FIG. 9(e), the test field 19 is imaged onto the sensor 31a with a homogeneous intensity, as shown in FIG. 9(f). The measurement accuracy is improved by the homogeneous illumination of the sensor 31a.

FIG. 10 illustrates a further example for compensating for an optical aberration. The optical aberration, which in the present case is attributable to the projection optics unit 22 and expressed by a decrease in intensity in the edge regions 35 of the pupil, is illustrated in FIG. 10(b) in the present case. FIG. 10(a) shows an illumination of the test field 19 that is required for compensating for the intensity distribution shown in FIG. 10(b). In combination with the weaker illumination of the edge regions 35, stronger illumination of the edge regions 36 leads to a homogeneous illumination of the sensor 31b (see FIG. 10(c)). A high level of illumination is illustrated by a darker color in FIG. 10, and a lower level of illumination is illustrated by a lighter color.

In some implementations, the processes described above that involve processing of data, e.g., analyzing images generated by the sensors 31a and 31b and performing alignment calibration, can be implemented by one or more computers (or computing devices), each computer can include one or more processor cores, and each processor core can include logic circuitry for processing data. In some implementations, the control unit 43 can also be implemented by one or more computers. For example, a processor can include an arithmetic and logic unit (ALU), a control unit, and various registers. Each processor can include cache memory. Each processor can include a system-on-chip (SoC) that includes multiple processor cores, random access memory, graphics processing units, one or more controllers, and one or more communication modules. Each processor can include millions or billions of transistors.

In some implementations, each of the one or more computers can include one or more data processors for processing data, one or more storage devices for storing data, and/or one or more computer programs including instructions that when executed by the one or more computers cause the one or more computers to carry out the processes. The one or more computers can include one or more input devices, such as a keyboard, a mouse, a touchpad, and/or a voice command input module, and one or more output devices, such as a display, and/or an audio speaker.

In some implementations, the one or more computing devices can include digital electronic circuitry, computer hardware, firmware, software, or any combination of the above. The features related to processing of data can be implemented in a computer program product tangibly embodied in an information carrier, e.g., in a machine-readable storage device, for execution by a programmable processor; and method steps can be performed by a programmable processor executing a program of instructions to perform functions of the described implementations. Alternatively or in addition, the program instructions can be encoded on a propagated signal that is an artificially generated signal, e.g., a machine-generated electrical, optical, or electromagnetic signal, that is generated to encode information for transmission to suitable receiver apparatus for execution by a programmable processor.

A computer program can be written in any form of programming language, including compiled or interpreted languages, and it can be deployed in any form, including as a stand-alone program or as a module, component, subroutine, or other unit suitable for use in a computing environment.

For example, the one or more computers can be configured to be suitable for the execution of a computer program and can include, by way of example, both general and special purpose microprocessors, and any one or more processors of any kind of digital computer. Generally, a processor will receive instructions and data from a read-only storage area or a random access storage area or both. Elements of a computer system include one or more processors for executing instructions and one or more storage area devices for storing instructions and data. Generally, a computer system will also include, or be operatively coupled to receive data from, or transfer data to, or both, one or more machine-readable storage media, such as hard drives, magnetic disks, solid state drives, magneto-optical disks, or optical disks. Machine-readable storage media suitable for embodying computer program instructions and data include various forms of non-volatile storage area, including by way of example, semiconductor storage devices, e.g., EPROM, EEPROM, flash storage devices, and solid state drives; magnetic disks, e.g., internal hard disks or removable disks; magneto-optical disks; and CD-ROM, DVD-ROM, and/or Blu-ray discs.

In some implementations, the processes described above can be implemented using software for execution on one or more mobile computing devices, one or more local computing devices, and/or one or more remote computing devices (which can be, e.g., cloud computing devices). For instance, the software forms procedures in one or more computer programs that execute on one or more programmed or programmable computer systems, either in the mobile computing devices, local computing devices, or remote computing systems (which may be of various architectures such as distributed, client/server, grid, or cloud), each including at least one processor, at least one data storage system (including volatile and non-volatile memory and/or storage elements), at least one wired or wireless input device or port, and at least one wired or wireless output device or port.

In some implementations, the software may be provided on a medium, such as CD-ROM, DVD-ROM, Blu-ray disc, a solid state drive, or a hard drive, readable by a general or special purpose programmable computer or delivered (encoded in a propagated signal) over a network to the computer where it is executed. The functions can be performed on a special purpose computer, or using special-purpose hardware, such as coprocessors. The software can be implemented in a distributed manner in which different parts of the computation specified by the software are performed by different computers. Each such computer program is preferably stored on or downloaded to a storage medium or device (e.g., solid state memory or media, or magnetic or optical media) readable by a general or special purpose programmable computer, for configuring and operating the computer when the storage media or device is read by the computer system to perform the procedures described herein. The inventive system can also be considered to be implemented as a computer-readable storage medium, configured with a computer program, where the storage medium so configured causes a computer system to operate in a specific and predefined manner to perform the functions described herein.

A number of embodiments of the invention have been described. Nevertheless, it will be understood that various modifications may be made without departing from the spirit and scope of the invention.

What is claimed is:

1. A measuring system for optically checking an alignment state of an illumination optics unit relative to a projection optics unit, the illumination optics unit being designed to illuminate an object situated in an object plane of the projection optics unit and the projection optics unit being designed to image a reflection generated at the object into an image plane of the projection optics unit, with the measuring system comprising:
a mount for positioning the illumination optics unit and the projection optics unit;
a partially transparent test object arranged in the object plane;
a measurement illumination unit for generating a measurement beam path, which illuminates a test field of the test object at the rear and is oriented such that the test field is imaged onto a first sensor plane by the illumination optics unit and imaged onto a second sensor plane by the projection optics unit;
a first sensor for capturing an image representation generated in the first sensor plane;
a second sensor for capturing an image representation generated in the second sensor plane;
a stop device arranged in the measurement beam path between an illumination source and the object plane and comprising a plurality of pixels which are each switchable between a first transmission state and a second transmission state; and
a control unit for switching the plurality of pixels between the first transmission state and the second transmission state.

2. The measuring system of claim 1, wherein the control unit is designed to optionally switch a first pixel into the first transmission state or into the second transmission state independently of a switching state of a second pixel different from the first.

3. The measuring system of claim 1, wherein the stop device comprises a pixel unit in the form of a liquid crystal display.

4. The measuring system of claim 1, wherein the stop device comprises a pixel unit comprising an absorption modulation material.

5. The measuring system of claim 1, wherein the stop device comprises a pixel unit formed by a microelectromechanical system.

6. The measuring system of claim 3, wherein the stop device comprises two pixel units, the pixels of which are oriented in such a way relative to one another that an achievable contrast ratio between the first transmission state and the second transmission state is increased.

7. The measuring system of claim 1, wherein the stop device comprises at least one of the following features:
a pixel dimension is greater than 10 μm and preferably between 100 μm and 400 μm;
a number of pixels is more than 100, preferably more than 1000 and more preferably between 100 and 1 000 000;
a contrast ratio of the stop device between the first transmission state and the second
transmission state is more than 1:10³ and preferably more than 1:10⁴ and further preferably more than 1:10⁶.

8. The measuring system of claim 1, wherein the control unit can switch any pixel of the stop device into an intermediate state in which a transmittance of the pixel is between the transmittances of the first transmission state and the second transmission state.

9. The measuring system of claim 8, wherein the control unit can switch any pixel into a plurality of intermediate states in each of which the pixel has a different transmittance, the transmittances being between the transmittance in the first transmission state and the transmittance in the second transmission state.

10. A method for optically checking an alignment state of an illumination optics unit relative to a projection optics unit, the illumination optics unit being designed to illuminate an object situated in an object plane of the projection optics unit and the projection optics unit being designed to image a reflection generated at the object into an image plane of the projection optics unit, comprising the following steps:
arranging a partially transparent test object in the object plane;
generating a measurement beam path, which illuminates a test field of the test object at the rear and is oriented such that the test field is imaged onto a first sensor plane by the illumination optics unit and imaged into a second sensor plane by the projection optics unit;
positioning a stop device in the measurement beam path between the illumination source and the object plane, the stop device comprising a plurality of pixels which are each switchable between a first transmission state and a second transmission state in order to optionally transmit or at least partially mask a beam of the measurement beam path corresponding to the respective pixel;
controlling the plurality of pixels in order to generate a predetermined measurement beam profile; and
capturing an image representation of the test field generated by the illumination optics unit and an image representation of the test field generated by the projection optics unit.

11. The method of claim 10, wherein the image representation of the test field generated by the illumination optics unit is captured while the second measurement beam is at least partially masked, wherein the image representation of the test field generated by the projection optics unit is captured while the first measurement beam is at least partially masked.

12. The method of claim 10, wherein an expected optical aberration of the illumination optics unit or an expected optical aberration of the projection optics unit is estimated, wherein the predetermined measurement beam profile is generated in such a way that the expected optical aberration of the illumination optics unit or of the projection optics unit is at least partially compensated for.

13. The method of claim 10, wherein the image representation of the test field generated by the illumination optics unit or by the projection optics unit is used to estimate an optical aberration of the illumination optics unit or of the projection optics unit, wherein the predetermined measurement beam profile is generated in such a way that the estimated optical aberration of the illumination optics unit or of the projection optics unit is at least partially compensated for.

14. A method for aligning an illumination optics unit relative to a projection optics unit, wherein a method of claim 10 is performed, wherein the image representation of the test field generated by the illumination optics unit and the image representation of the test field generated by the projection optics unit are used to align the illumination optics unit relative to the projection optics unit.
